(19) United States
(12) Patent Application Publication
(10) Pub. No.: US 2005/0255389 A1
(43) Pub. Date: Nov. 17, 2005

(54) Phase shift mask and method of producing the same

(75) Inventors: Koji Tange, Hyogo (JP); Kunihiro Hosono, Hyogo (JP); Satoshi Aoyama, Hyogo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/119,911

(22) Filed: May 3, 2005

(30) Foreign Application Priority Data
May 11, 2004 (JP) 2004-141057

(51) Int. Cl. G03F 9/00; G03C 5/00

(52) U.S. Cl. 430/5; 430/322; 430/323; 430/324

(57) ABSTRACT

A light shielding film, a halftone film, an etching stopper film and a transparent substrate are dry etched to form a hole penetrating the films and extending in the substrate through a main surface thereof to a prescribed depth. The etching stopper film is formed of a material significantly high in selectivity relative to the substrate under a condition for etching the substrate. This prevents the etching stopper film and the substrate in the step of etching the substrate from being etched to extend a geometry of a pattern in a direction parallel to the substrate's main surface.

### BACKGROUND OF THE INVENTION

1. Field of the Invention

The present invention relates generally to phase shift masks and methods of producing the same, and particularly to phase shift masks having a halftone mask deposited on a transparent substrate and methods of producing the same.

Conventionally a phase shift mask having a halftone film deposited on a transparent substrate has been used. In such a phase shift mask an in-phase halftone edge enhancement phase shift mask is particularly effectively used. This mask is formed by initially forming a blanks structure and then dry etching individual films configuring the blanks structure. The blanks structure is formed of a transparent substrate, a halftone film deposited on the transparent substrate, and a light shielding film deposited on the halftone film.

2. Description of the Background Art

For the above conventional phase shift mask the transparent substrate dry etched has an insufficient selection ratio relative to the halftone film. As such, while the transparent substrate is dry etched, the halftone film is etched further in a direction parallel to the substrate's main surface, and the substrate is accordingly also etched further in a direction parallel to its main surface. As a result, the substrate can disadvantageously be patterned in a geometry significantly different from that as intended. If the phase shift mask having on the transparent substrate a pattern of a geometry significantly different from that intended is used in a semiconductor device fabrication process to perform an exposure step, the semiconductor device will be patterned in a geometry significantly different from that intended, and thus impaired in performance.

### SUMMARY OF THE INVENTION

The present invention has been made to overcome the above disadvantage and it contemplates a phase shift mask and its production method capable of providing a geometry of a pattern formed in a phase shift mask at a transparent substrate that is closer to that of a pattern intended.

The present phase shift mask includes: a transparent substrate having a patterned portion formed to extend from a main surface thereof to a prescribed depth, and an exposed portion adjacent to the patterned portion and exposing a main surface thereof; a film overlying the transparent substrate and adjacent to the exposed portion; and a halftone film overlying the film overlying the substrate. Light transmitted through the patterned portion and that transmitted through the halftone film and the film overlying the substrate are substantially in phase. Light transmitted through the exposed portion and that transmitted through the patterned portion are substantially opposite in phase, and light transmitted through the exposed portion and that transmitted through the halftone film and the film overlying the substrate are also substantially opposite in phase. Furthermore, the film overlying the substrate and the halftone film are different in material.

Thus if the film overlying the substrate has a prescribed selectivity relative to the substrate the film can be used as an etching stopper film to provide the substrate with a patterned portion. This can prevent the patterned portion from having a geometry disadvantageously larger in a direction parallel to the main surface than intended. The patterned portion can thus be formed to have a geometry close to that intended.

The present invention in one aspect provides a method of producing a phase shift mask, including the steps of: depositing on a transparent substrate an etching stopper film having a prescribed selectivity relative to the transparent substrate and serving as an etching mask in dry etching the transparent substrate; depositing a halftone film on the etching stopper film; depositing a light shielding film on the halftone film; depositing on the light shielding film a first resist film having a first prescribed pattern; successively dry etching through the first resist film serving as an etching mask the light shielding film, the halftone film, the etching stopper film, and a portion of the transparent substrate extending from a main surface thereof to a prescribed depth; removing the first resist film; depositing on the light shielding film a second resist film having a second prescribed pattern different from the first prescribed pattern; dry etching through the second resist film serving as an etching mask the light shielding film, the halftone film and the etching stopper film successively; removing the second resist film; depositing on the light shielding film a third resist film having a pattern different from the first and second prescribed patterns; and etching through the third resist film serving as an etching mask to remove the light shielding film.

In the above described method at the step of successively dry etching through the first resist film the transparent substrate is dry etched with the etching stopper film thereon. As compared with the transparent substrate etched without the etching stopper film thereon, the transparent substrate etched with the etching stopper film thereon can be patterned to have a geometry closer to that intended.

Furthermore the present invention in another aspect provides a method of producing a phase shift mask, including the steps of: depositing on a transparent substrate an etching stopper film having a prescribed selectivity relative to the transparent substrate and serving as an etching mask in dry etching the transparent substrate; depositing a halftone film on the etching stopper film; depositing a light shielding film on the halftone film; depositing on the light shielding film a first resist film having a first prescribed pattern; successively dry etching through the first resist film serving as an etching mask the light shielding film, the halftone film, the etching stopper film, and a portion of the transparent substrate extending from a main surface thereof to a prescribed depth; removing the first resist film; depositing on the light shielding film a second resist film having a second prescribed pattern different from the first prescribed pattern; dry etching through the second resist film serving as an etching mask the light shielding film and the halftone film successively; removing the second resist film; depositing on the light shielding film a third resist film having a pattern different from the first and second prescribed patterns; and etching through the third resist film serving as an etching mask to remove the light shielding film and the etching stopper film.

Furthermore in the method in the above described another aspect the etching stopper film and the light shielding film are formed of material removable by the same etchant gas and the light shielding film and the etching stopper film are removed by the same etchant gas simultaneously.

The above described method provides an effect similar to that of the phase shift mask of the aforementioned one aspect and in addition thereto, as compared with a method that removes the light shielding film and the etching stopper film separately, allows a phase shift mask to be produced through a process reduced by one step.

The present invention in still another aspect provides a method of producing a phase shift mask, including the steps of: depositing on a transparent substrate an etching stopper film having a prescribed selectivity relative to the transparent substrate and serving as an etching mask in dry etching the transparent substrate; depositing a halftone film on the etching stopper film; depositing a light shielding film on the halftone film; depositing on the light shielding film a first resist film having a first prescribed pattern; etching the light shielding film and the halftone film through the first resist film serving as an etching mask to expose a surface of the etching stopper film; depositing a second resist film having a second prescribed pattern to cover a portion of an upper surface of the etching stopper film exposed, a side surface of the halftone film, and side and upper surfaces of the light shielding film; successively dry etching through the second resist film serving as an etching mask the etching stopper film and the transparent substrate at a portion extending from a main surface of the transparent substrate to a prescribed depth; removing the second resist film; depositing on the light shielding film a third resist film having a pattern different from the first and second prescribed patterns; and etching through the third resist film serving as an etching mask to remove the light shielding film and the etching stopper film.

In the above described method at the step of successively dry etching through the second resist film the transparent substrate is dry etched with the etching stopper film thereon. As compared with the transparent substrate dry etched without the etching stopper film thereon, the transparent substrate dry etched with the etching stopper film thereon can be patterned to have a geometry closer to that intended.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1-14 illustrate a process for producing a phase shift mask of a first embodiment.

FIGS. 15-17 illustrate an exemplary variation of the process for producing the phase shift mask of the first embodiment.

FIGS. 18-20 illustrate a structure of the phase shift mask of the first embodiment.

FIGS. 21-30 illustrate a process for producing a phase shift mask in a second embodiment.

### DESCRIPTION OF THE PREFERRED EMBODIMENTS

Hereinafter with reference to the drawings the present method of producing a phase shift mask in embodiments will be described.

### First Embodiment

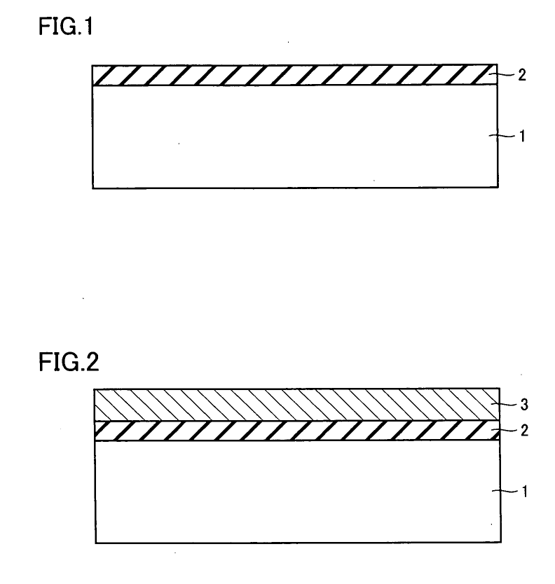

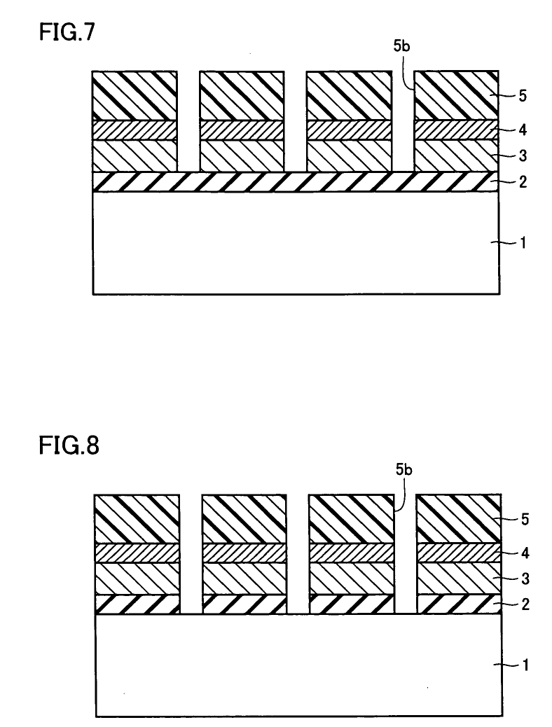

With reference to FIGS. 1-20 a first embodiment provides a method of producing a phase shift mask and its structure formed thereby will be described.

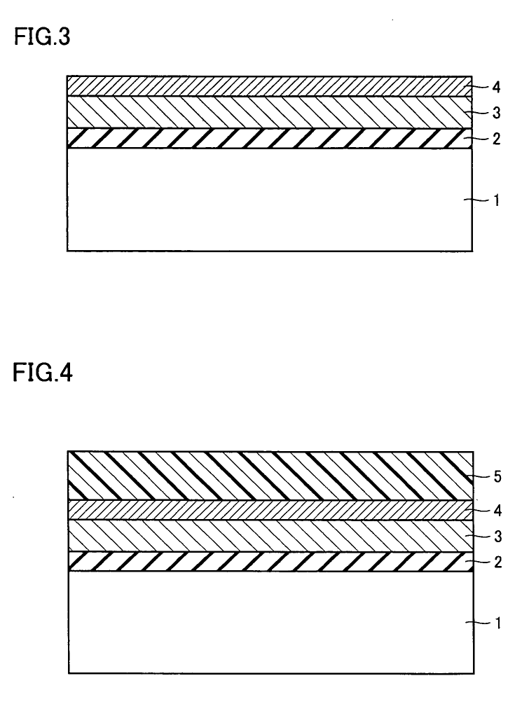

In the present embodiment the method is performed as follows: initially, as shown in FIG. 1, a transparent substrate 1 has deposited thereon an etching stopper film 2 having a prescribed selectivity relative to transparent substrate 1 and serving as an etching mask for transparent substrate 1 in a step later performed to dry etch the substrate. Then, as shown in FIG. 2, etching stopper film 2 has a halftone film 3 deposited thereon. Then, as shown in FIG. 3, halftone film 3 has a light shielding film 4 deposited thereon. Then, as shown in FIG. 4, light shielding film 4 has a resist film 5 deposited thereon.

Note that in the present embodiment transparent substrate 1 is desirably formed of quartz. Etching stopper film 2 is desirably formed of a film containing hafnium oxide as a main component, a film containing Al₂O₃ and SnO₂, a chromium oxide film, a chromium nitride film, or the like. Halftone film 3 is desirably formed of MoSi film and has an optical transmittance of 3% to 8%, although halftone film 3 having an optical transmittance of 25% or less allows the present invention's object to be achieved. Furthermore, light shielding film 4 is desirably formed of Cr film and has an optical transmittance of approximately 0.1% or less, i.e., shields 99.9% or more of light.

Furthermore, if the selectivity of transparent substrate 1 relative to etching stopper film 2 in dry etching transparent substrate 1 with a prescribed etchant gas is larger than that of transparent substrate 1 relative to halftone film 3 in dry etching transparent substrate 1 with the prescribed etchant gas, providing etching stopper film 2 on transparent substrate 1 can prevent the substrate from being significantly etched in a direction extending along its surface. Accordingly in the present specification etching stopper film 2 having a prescribed selectivity relative to transparent substrate 1 means an etching stopper film formed of a material providing for the aforementioned effect.

Desirably the transparent substrate has a selectivity of at least two and at most three relative to the etching stopper film. The selectivity of at least two can prevent etching stopper film 2 from being etched in a direction parallel to the transparent substrate 1 main surface so that transparent substrate 1 will be patterned in a geometry also extending in a direction parallel to the substrate's main surface. The selectivity of at most three allows transparent substrate 1 to more controllably be patterned depthwise or in a direction perpendicular to the substrate's main surface. Note that in the present specification a selectivity of a transparent substrate relative to an etching stopper film is a ratio of an etching rate of the substrate relative to that of the film under a prescribed etching condition (e.g., an etchant gas).

The aforementioned matters are similar applied in a method of producing a phase shift mask in a second embodiment as described later.

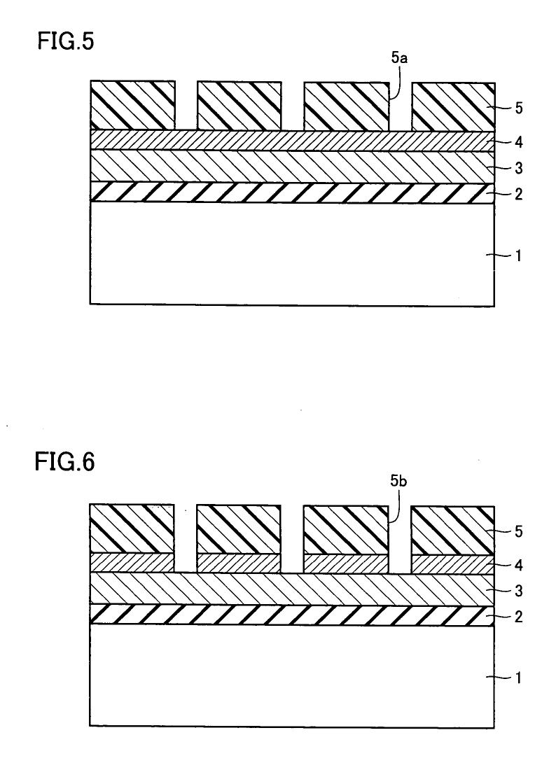

Then, as shown in FIG. 5, a photolithography step is performed to provide resist film 5 with a prescribed pattern to have a hole 5a having a bottom surface exposing light shielding film 4 at a surface partially. Hole 5a has a pattern having a geometry corresponding to that of a portion of transparent substrate 1 to be dry etched, as will be described later, and corresponding to a portion 10 of transparent substrate 1 transmitting light of a phase of π in a step of exposing a semiconductor substrate to light.

Then, with reference to FIGS. 6-9, resist film 5 having hole 5a is used as an etching mask to dry etch light shielding film 4, halftone film 3, etching stopper film 3, and transparent substrate 1. At this stage, transparent substrate 1 dry etched has portion 10 shallower than that finally provided. Note that drawing and development steps performed in patterning resist film 5 to provide hole 5a as shown in the FIG. 5 are conventionally performed.

Furthermore, as shown in FIGS. 6-9, light shielding film 4, halftone film 3, etching stopper film 2, and transparent substrate 1 are removed downward successively in different steps, respectively, as an etchant gas or other etching condition is changed so that a layer to be etched has a prescribed selectivity relative to an underlying layer. Subsequently, resist film 5 is ashed and thus removed.

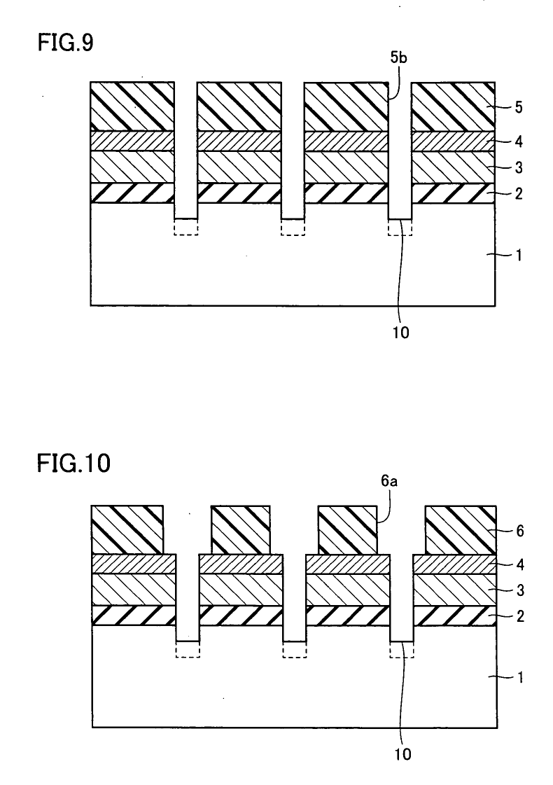

More specifically, after the FIG. 5 structure is formed when transparent substrate 1 is to be dry etched, light shielding film 4, halftone film 3 and etching stopper film 2 have a pattern of an opening corresponding to hole 5a shown in FIG. 5 and transparent substrate 1 is dry etched with an etchant gas and thus removed at a portion corresponding to the pattern of the opening to form a hole 5b shown in FIG. 9. In doing so, etching stopper film 2 is hardly etched by the etchant gas dry etching transparent substrate 1.

Then, as shown in FIG. 10, a resist film 6 having a hole 6a is deposited on light shielding film 4. Resist film 6 is also deposited by a step in which drawing and development substeps are conventionally performed. Furthermore, hole 6a has a pattern having a geometry corresponding to a pattern of a perimeter of a portion of the transparent substrate that transmits light of a phase of 0°.

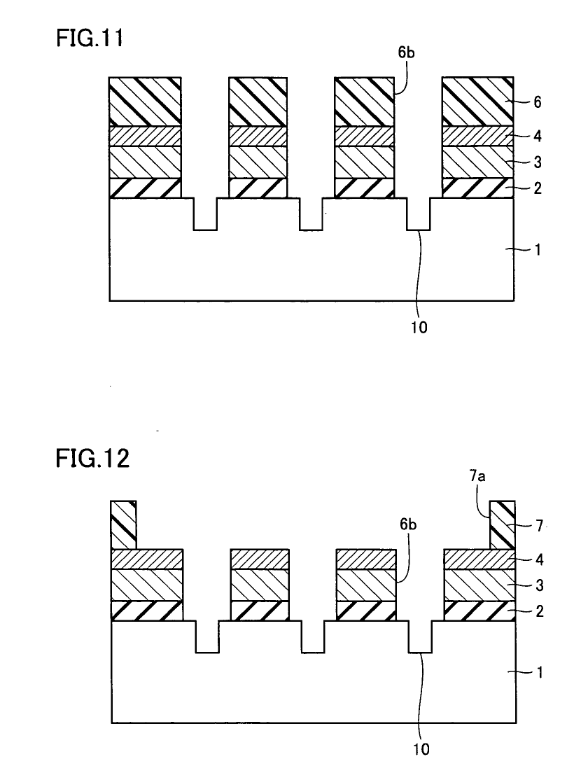

Then, as shown in FIG. 10, resist film 6 having the hole 6a pattern is used as an etching mask and light shielding film 4, halftone film 3 and etching stopper film 2 are thus dry etched away. Note that light shielding film 4, halftone film 3, and etching stopper film 2 are removed downward successively in different steps, respectively, as an etchant gas or other etching condition is changed so that a layer to be etched has a prescribed selectivity relative to an underlying layer. The step shown in FIG. 11 is performed with an etchant gas or similar etching condition varied similarly as done in FIGS. 6-8 steps. As a result, as shown in FIG. 11, resist film 6, light shielding film 4, halftone film 3, and etching stopper film 2 are penetrated by hole 6b.

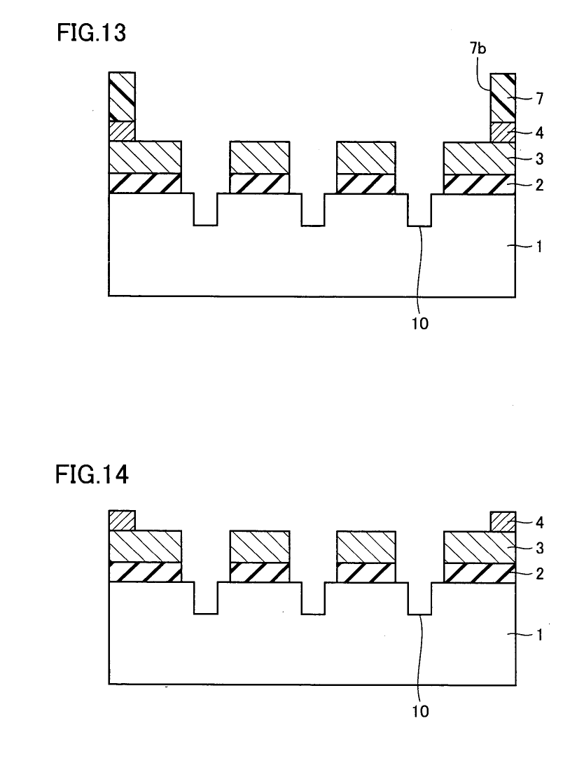

Then, resist film 6 is removed. Subsequently, as shown in FIG. 12, a resist film 7 having a hole 7a is deposited. Hole 7a has a geometry corresponding to that of a perimeter of a region of a portion at which light is transmitted through halftone film 3 in a step of exposing a semiconductor substrate to light. Then, resist film 7 having hole 7a is used as an etching mask and light shielding film 4 is thus dry etched away. As a result, as shown in FIG. 13, a hole 7b is formed in resist film 7 and light shielding film 4. Subsequently, resist film 7 is removed to provide a structure shown in FIG. 14.

In the present phase shift mask production method of the present embodiment as described above the FIG. 8 structure has transparent substrate 1 dry etched with etching stopper film 2 high in selectivity relative to transparent substrate 1 deposited on transparent substrate 1 so that transparent substrate 1 can have portion 10 transmitting light of the phase of π that has a geometry close to that intended. More specifically, in etching transparent substrate 1, etching stopper film 2 is not etched further in a direction parallel to the substrate's main surface. Accordingly, portion 10, at which light transmitted therethrough has the phase of π, also has a contour that does not extend in the direction parallel to the substrate's main surface. Consequently, portion 10 does not have a geometry significantly different from that intended. As such, when the present embodiment's phase shift mask is used to perform a step of exposing a semiconductor device to light, the semiconductor device can be patterned to have a geometry close to that intended and thus have characteristics close to performance as intended.

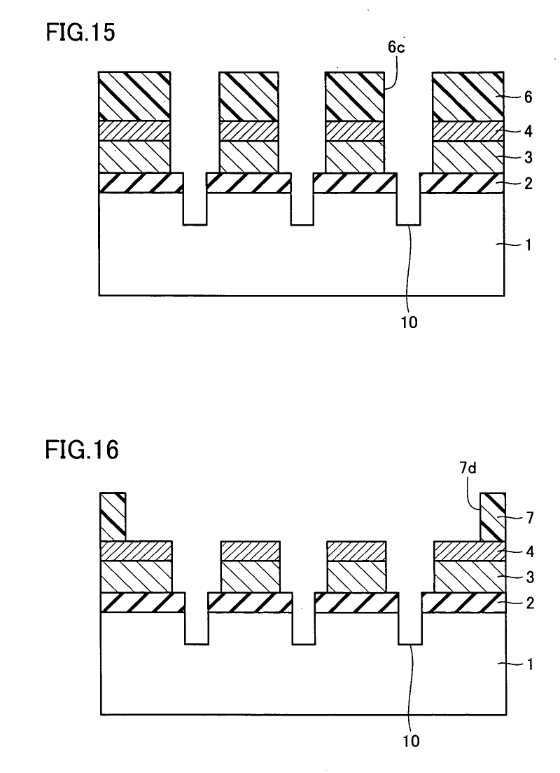

In the present embodiment the aforementioned FIGS. 11-14 steps are shown. Desirably, however, steps shown in FIGS. 15-17 are performed, as follows: initially, when the FIG. 10 structure is being formed, resist film 6 having hole 6a is used as an etching mask and light shielding film 4 and halftone film 3 are thus dry etched with an etchant gas or similar etching condition varied so that films 4 and 3 are removed downward successively in independent steps, respectively, to form hole 6c. Thus the FIG. 15 structure is obtained. At this stage, etching stopper film 2 is exposed as a portion of a bottom surface of hole 6c.

Subsequently, resist film 6 is removed, and then, as shown in FIG. 16, a photolithography step is performed to deposit on light shielding film 4 a resist film 7 having a hole 7d. Then, as shown in FIG. 17, resist film 7 having hole 7d is used as an etching mask and light shielding film 4 and etching stopper film 2 are simultaneously dry etched to provide resist film 7 and light shielding film 4 with a hole 7e and also provide halftone film 3 and etching stopper film 2 with a hole 3x as shown in FIG. 17.

For the FIGS. 15-17 phase shift mask production process light shielding film 4 and etching stopper film 2 are formed of material that can be removed by the same etching gas. As such, when the FIG. 16 structure is etched with resist film 7d of a pattern having hole 7d used as an etching mask, light shielding film 4 and etching stopper film 2 are simultaneously removed. Thus the FIGS. 15-17 phase shift mask production method can eliminate the necessity of performing separate, independent etching steps to separately remove light shielding film 4 and etching stopper film 2. A simplified production process can be achieved.

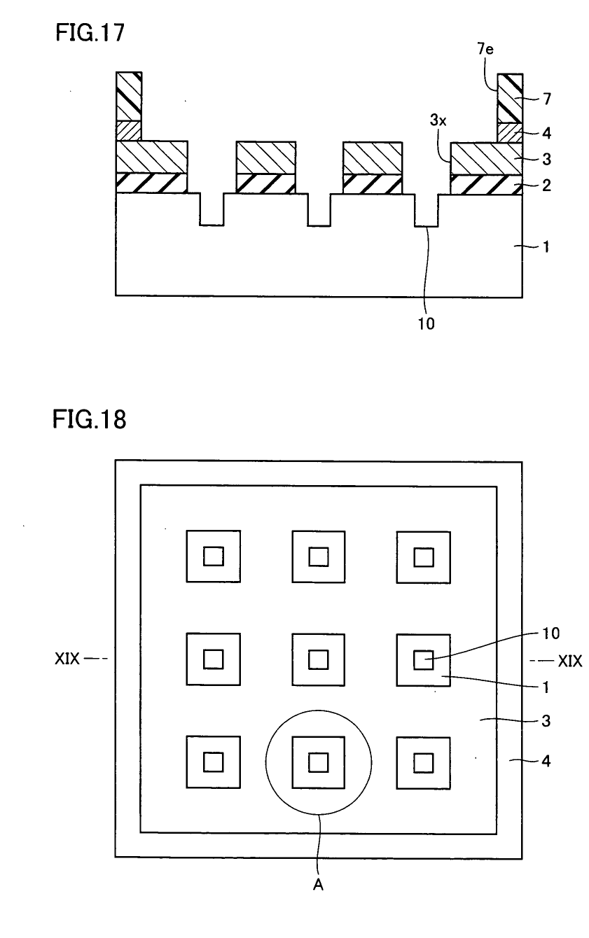

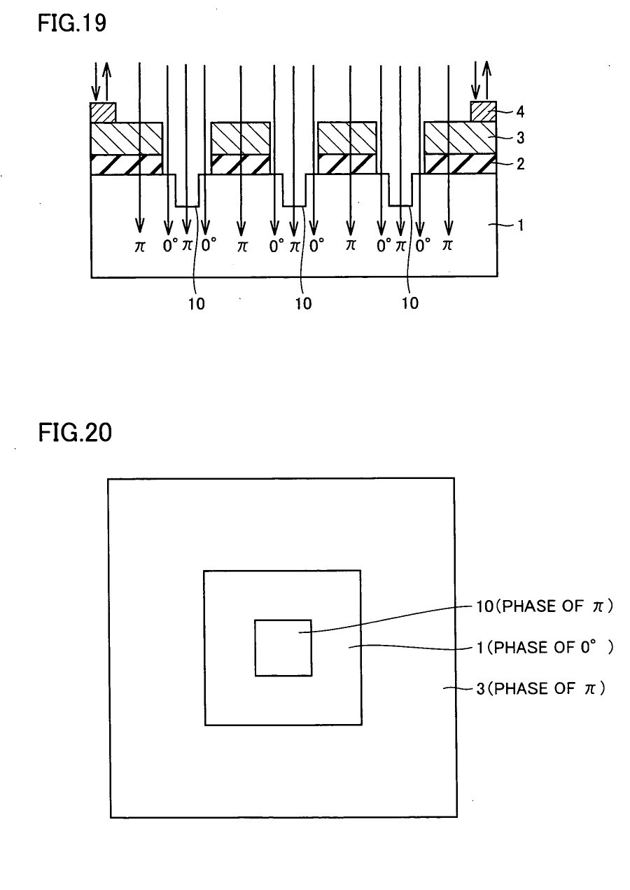

The phase shift mask production method of the present embodiment as described above produces a phase shift mask having a structure as shown in FIGS. 18-20. As can be seen from the plan view shown in FIG. 18, the phase shift mask has light shielding film 4 segmenting a region and therein halftone film 3 surrounds transparent substrate 1 to provide a plurality of regions As. The plurality of regions As, exposing transparent substrate 1, are each provided with an exposed portion of the main surface of transparent substrate 1 transmitting light of the phase of 0°, and portion 10 of the substrate transmitting light of the phase of π. Furthermore, the exposed portion of the main surface of substrate 1 surrounds portion 10. Furthermore, half tone film 3 has an exposed main surface, which passes light of the phase of π therethrough. When the FIG. 18 structure is seen in a cross section taken along a line XIX-XIX, it provides a structure as shown in FIG. 19. Furthermore, when region A including the exposed portion of the main surface of transparent substrate 1, as seen in an enlarged view, has a structure as shown in FIG. 20.

In the phase shift mask having the structure shown in FIGS. 19 and 20, light transmitted through portion 10 has a phase shifted by π and that transmitted through the exposed surface of transparent substrate 1 is not phase-shifted. In other words, transparent substrate 1 at the exposed main surface transmits light of the phase of 0° and light impinging on halftone film 3 at an exposed main surface and thus transmitted through the substrate has a phase shifted by π. In FIG. 19, an arrow indicates a direction in which light travels and a letter written at the head of the arrow indicates a phase of light traveling in the direction indicated by the arrow.

As such, in a vicinity of a border of portion 10 and a portion having the transparent substrate 1 main surface exposed, light transmitted through portion 10 and that transmitted through the portion having the substrate's main surface exposed cancel each other. Furthermore in a vicinity of a border of the portion having the transparent substrate 1 main surface exposed and halftone film 3, light transmitted through the portion having the substrate's main surface exposed and that transmitted through halftone film 3 cancel each other. Consequently in a semiconductor device fabrication process at an exposure step the borders are more clearly transferred to a prescribed position of an intermediate product of a semiconductor device being fabricated.

### Second Embodiment

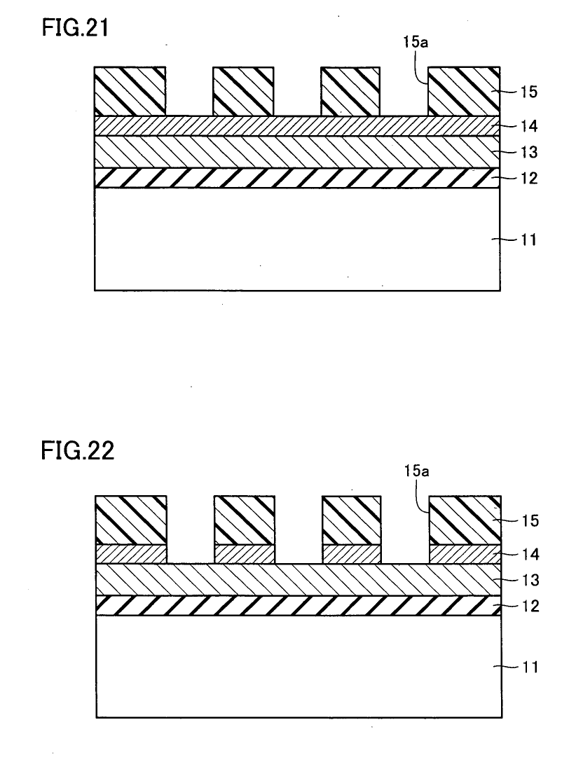

With reference to FIGS. 21-30, a second embodiment provides a phase shift mask production method, as will be described hereinafter. In the present embodiment, initially a transparent substrate 11, an etching stopper film 12, a halftone film 13, a light shielding film 14 and a resist film 15 are successively deposited in layers. The FIG. 21 structure is formed through exactly the same steps as described in the first embodiment with reference to FIGS. 1-5.

In the present embodiment initially as shown in FIG. 21 light shielding film 14 has deposited thereon resist film 15 having a hole 15a having a pattern corresponding in geometry to a contour of a portion of transparent substrate 11 that transmits light of the phase of 0°, as will be described later.

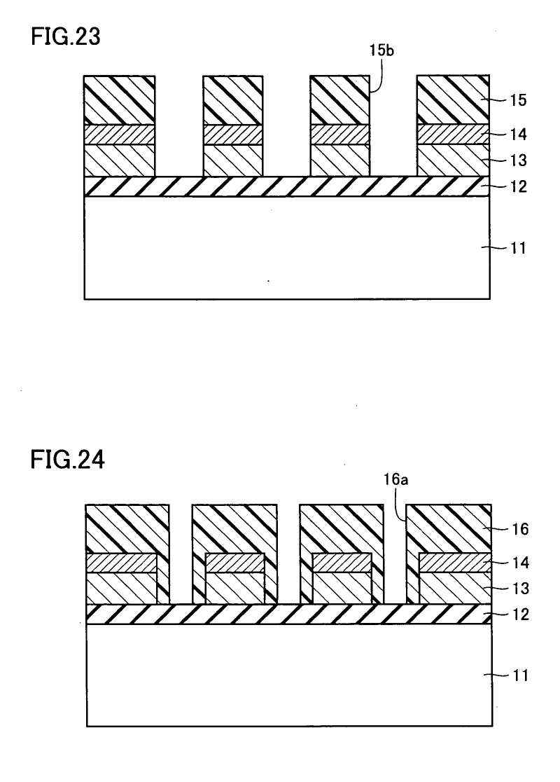

Then, as shown in FIGS. 22 and 23, resist film 15 having the pattern of hole 15a is used as an etching mask and light shielding film 14 and halftone film 13 are thus dry etched to expose a portion of a surface of etching stopper film 12. Light shielding film 14 and halftone film 13 are removed downward successively at separate, independent steps, respectively, as an etchant gas or similar etching condition is varied. Thus, as shown in FIG. 23, resist film 15, light shielded film 14 and halftone film 13 are provided with a hole 15b having a bottom surface exposing a portion of the main surface of etching stopper film 12.

Then, as shown in FIG. 24, a resist film 16 having a pattern of a hole 16a is formed. Resist film 16 is deposited to cover a portion of the exposed surface of etching stopper film 12, a side surface of halftone film 13, and side and top surfaces of light shielding film 14. Hole 16a has a geometry corresponding to a portion 20 of transparent substrate 11 that transmits light of the phase of π, as will be described later.

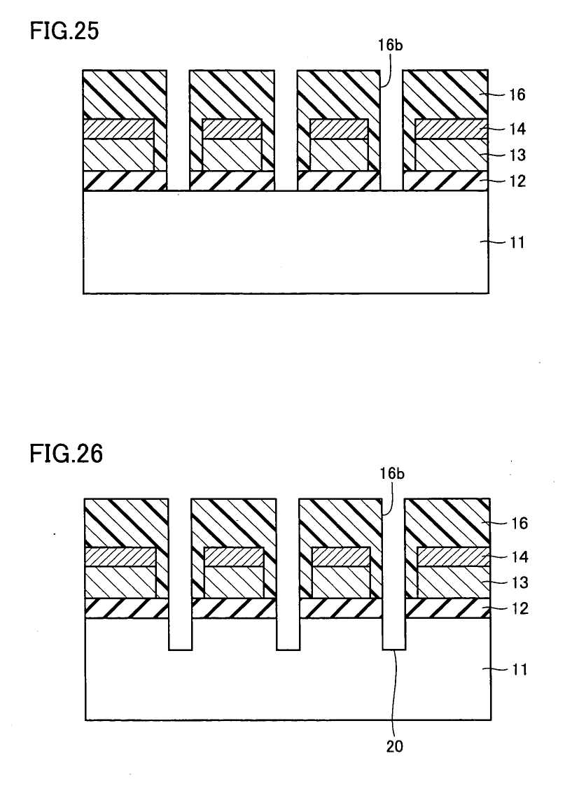

Resist film 16 having the pattern of hole 16a is used to dry etch etching stopper film 12. This forms a hole 16b defined by resist film 16 and an opening of etching stopper film 12, as shown in FIG. 25. Subsequently, etching stopper film 12 is used as a mask and transparent substrate 11 is thus dry etched. Thus, as shown in FIG. 26, hole 16b is provided at a bottom portion with portion 20 allowing transparent substrate 1 to transmit light of the phase of π.

More specifically, after the FIG. 25 structure is formed when transparent substrate 11 is to be dry etched, etching stopper film 12 has hole 16b and transparent substrate 11 is dry etched with an etchant gas and thus removed at a portion corresponding to the pattern of the opening of hole 16b to form portion 20 transmitting light of the phase of π, as shown in FIG. 26. Etching stopper film 12 is hardly etched by the etchant gas dry etching transparent substrate 1.

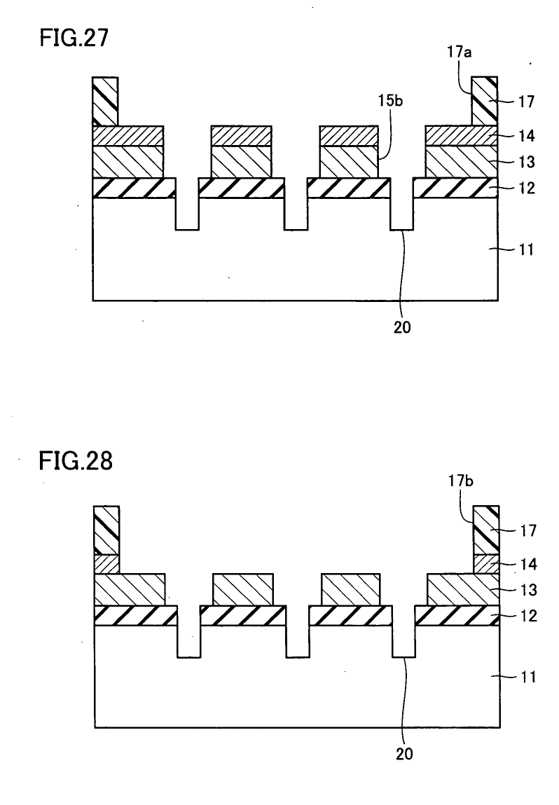

Then, resist film 16 is removed. Subsequently on light shielding film 14 a resist film 17 having a pattern of a hole 17a is deposited. As a result, as shown in FIG. 27, light shielding film 14 and halftone film 13 are provided with a pattern of hole 15b.

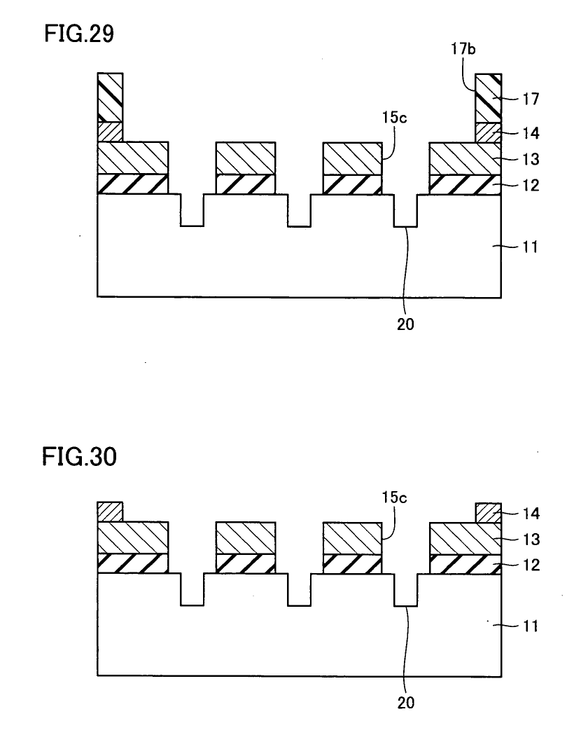

Note that light shielding film 14 and etching stopper film 12 are formed of different materials that are not etched with the same etchant gas. Accordingly, as shown in FIG. 28, light shielding film 14 alone is initially etched. Then an etchant gas or similar etching condition is changed for etching etching stopper film 12 to partially remove etching stopper film 12 to obtain a structure as shown in FIG. 29. Resist film 17 is then removed to provide a structure shown in FIG. 30.

In the present embodiment's phase shift mask production method, as well as the first embodiment's phase shift mask production method, in the FIG. 25 condition transparent substrate 11 with etching stopper film 12 thereon is dry etched. Etching stopper film 12 prevents transparent substrate 11 from being etched further in a direction parallel to a main surface of transparent substrate 11. This prevents transparent substrate 11 from having portion 20 transmitting light of the phase of π that has a geometry of a pattern extending along the surface of transparent substrate 11. As a result, the present embodiment's method also provides a phase shift mask having portion 20 transmitting light of a phase of 180° that has a geometry close to that as intended. As such, when an intermediate product of a semiconductor device being fabricated is subjected to an exposure step through the phase shift mask of the present embodiment the intermediate product can have transferred thereon a pattern having a geometry close to that of a pattern intended. This can fabricate a semiconductor device having a geometry of a pattern closer to the intended pattern and thus enhanced in performance.

Note that the FIGS. 27-29 steps may be replaced with the following process:

After the FIG. 27 structure is provided, resist film 17 is used as an etching mask and light shielding film 14 and etching stopper film 12 are simultaneously dry etched. Films 14 and 12 are formed of material simultaneously removed by the same etchant gas. The FIG. 29 structure is thus obtained. More specifically in this process the two steps for forming the FIG. 29 structure from the FIG. 27 structure can be performed by a single step. More specifically, the two steps shown in FIGS. 28 and 29 can be provided in a single step. A simplified phase shift mask production process can thus be provided.

Note that the present embodiment's phase shift mask production method also provides a phase shift mask having a structure described in the first embodiment and shown in FIGS. 19 and 20.

Although the present invention has been described and illustrated in detail, it is clearly understood that the same is by way of illustration and example only and is not to be taken by way of limitation, the spirit and scope of the present invention being limited only by the terms of the appended claims.

1. A phase shift mask comprising:
a transparent substrate having a patterned portion formed to extend from a main surface thereof to a prescribed depth, and an exposed portion adjacent to said patterned portion and exposing a main surface thereof,
a film overlying said transparent substrate and adjacent to said exposed portion; and
a halftone film overlying said film overlying said substrate, wherein:
light transmitted through said patterned portion and that transmitted through said halftone film and said film overlying said substrate are substantially in phase;
light transmitted through said exposed portion and that transmitted through said patterned portion are substantially opposite in phase, and light transmitted through said exposed portion and that transmitted through said halftone film and said film overlying said substrate are also substantially opposite in phase; and
said film overlying said substrate and said halftone film are different in material.

2. The phase shift mask according to claim 1, wherein:
said film overlying said substrate has a prescribed selectively relative to said transparent substrate; and
said transparent substrate and said film overlying said substrate are formed of such materials that said transparent substrate's selection ratio relative to said film overlying said substrate is at least two.

3. The phase shift mask according to claim 1, wherein:
said transparent substrate includes quartz as a main component; and
said film overlying said substrate includes at least one substance selected from the group consisting of a film containing hafnium oxide as a main component, a film containing Al₂O₃ and SnO₂, a chromium oxide film, and a chromium nitride film.

4. A method of producing a phase shift mask, comprising the steps of:
depositing on a transparent substrate an etching stopper film having a prescribed selectivity relative to said transparent substrate and serving as an etching mask in dry etching said transparent substrate;
depositing a halftone film on said etching stopper film;
depositing a light shielding film on said halftone film;
depositing on said light shielding film a first resist film having a first prescribed pattern;
successively dry etching through said first resist film serving as an etching mask said light shielding film, said halftone film, said etching stopper film, and a portion of said transparent substrate extending from a main surface thereof to a prescribed depth;
removing said first resist film;
depositing on said light shielding film a second resist film having a second prescribed pattern different from said first prescribed pattern;
dry etching through said second resist film serving as an etching mask said light shielding film, said halftone film and said etching stopper film successively;
removing said second resist film;
depositing on said light shielding film a third resist film having a pattern different from said first and second prescribed patterns; and
etching through said third resist film serving as an etching mask to remove said light shielding film.

5. The method according to claim 4, wherein said transparent substrate's selection ratio relative to said etching stopper film is at least two.

6. The method according to claim 4, wherein:
said transparent substrate includes quartz as a main component; and
said etching stopper film includes at least one substance selected from the group consisting of a film containing hafnium oxide as a main component, a film containing Al₂O₃ and SnO₂, a chromium oxide film, and a chromium nitride film.

7. A method of producing a phase shift mask, comprising the steps of:
depositing on a transparent substrate an etching stopper film having a prescribed selectivity relative to said transparent substrate and serving as an etching mask in dry etching said transparent substrate;
depositing a halftone film on said etching stopper film;
depositing a light shielding film on said halftone film;
depositing on said light shielding film a first resist film having a first prescribed pattern;
successively dry etching through said first resist film serving as an etching mask said light shielding film, said halftone film, said etching stopper film, and a portion of said transparent substrate extending from a main surface thereof to a prescribed depth;
removing said first resist film;
depositing on said light shielding film a second resist film having a second prescribed pattern different from said first prescribed pattern;
dry etching through said second resist film serving as an etching mask said light shielding film and said halftone film successively;
removing said second resist film;
depositing on said light shielding film a third resist film having a pattern different from said first and second prescribed patterns; and
etching through said third resist film serving as an etching mask to remove said light shielding film and said etching stopper film, wherein:
said etching stopper film and said light shielding film are formed of material removable by a same etchant gas;
in the step of etching through said third resist film said light shielding film and said etching stopper film are simultaneously removed by said same etchant gas.

8. The method according to claim 7, wherein said transparent substrate's selection ratio relative to said etching stopper film is at least two.

9. The method according to claim 7, wherein:
said transparent substrate includes quartz as a main component; and
said etching stopper film includes at least one substance selected from the group consisting of a film containing hafnium oxide as a main component, a film containing Al₂O₃ and SnO₂, a chromium oxide film, and a chromium nitride film.

10. A method of producing a phase shift mask, comprising the steps of:
depositing on a transparent substrate an etching stopper film having a prescribed selectivity relative to said transparent substrate and serving as an etching mask in dry etching said transparent substrate;
depositing a halftone film on said etching stopper film;
depositing a light shielding film on said halftone film;
depositing on said light shielding film a first resist film having a first prescribed pattern;
etching said light shielding film and said halftone film through said first resist film serving as an etching mask to expose a surface of said etching stopper film;
depositing a second resist film having a second prescribed pattern to cover a portion of an upper surface of said etching stopper film exposed, a side surface of said halftone film, and side and upper surfaces of said light shielding film;
successively dry etching through said second resist film serving as an etching mask said etching stopper film and said transparent substrate at a portion extending from a main surface of said transparent substrate to a prescribed depth;
removing said second resist film;
depositing on said light shielding film a third resist film having a pattern different from said first and second prescribed patterns; and
etching through said third resist film serving as an etching mask to remove said light shielding film and said etching stopper film.

11. The method according to claim 10, wherein
said etching stopper film and said light shielding film are formed of material removable by a same etchant gas;
in the step of etching through said third resist film said light shielding film and said etching stopper film are simultaneously removed by said same etchant gas.

12. The method according to claim 10, wherein said transparent substrate's selection ratio relative to said etching stopper film is at least two.

13. The method according to claim 10, wherein:
said transparent substrate includes quartz as a main component; and
said etching stopper film includes at least one substance selected from the group consisting of a film containing hafnium oxide as a main component, a film containing Al₂O₃ and SnO₂, a chromium oxide film, and a chromium nitride film.
